(19) United States
(12) Patent Application Publication
(10) Pub. No.: US 2025/0141312 A1
(43) Pub. Date: May 1, 2025

(54) UVW INTERFACE HAVING AT LEAST ONE ELECTROMAGNETIC DAMPING FEATURE

(71) Applicant: Vitesco Technologies USA, LLC, Auburn Hills, MI (US)

(72) Inventors: Venkat Hanuma Sriram Nukala, Troy, MI (US); Bianca Barduchi, Tlaquepaque (MX); Bertrand L. Dinger, JR., Farmington, MI (US); Diana Rizo, Troy, MI (US); Toni Zimmermann, Erlangen (DE); Daniel Ivan Perez Cano, Chihauhua (MX)

(73) Assignee: Vitesco Technologies USA, LLC, Auburn Hills, MI (US)

(21) Appl. No.: 18/498,429

(22) Filed: Oct. 31, 2023

(51) Int. Cl. H02K 11/02; H01R 9/22; H02K 3/50

(52) U.S. Cl. CPC H02K 11/02; H01R 9/223; H02K 3/50; H02K 2203/09

(57) ABSTRACT

An AC carrier assembly, which includes a housing, a receptacle integrally formed as part of the housing, a plurality of busbars extending through the housing, a core at least partially disposed in the receptacle, the core surrounding the busbars to dampen electromagnetic interference. A plurality of sub-housings are integrally formed as part of the housing, and each of a plurality of flux concentrators, is disposed in a corresponding one of the sub-housings. The AC carrier assembly also includes a cover attached to the housing, and a plurality of conductors. Each of the conductors is connected one of the busbars, and each of the flux concentrators surrounds a corresponding one of the busbars. Each sub-housing includes a cavity, and one of the flux concentrators is at least partially disposed in the cavity of the sub-housing. Each sub-housing may be overmolded around the flux concentrators.

### FIELD OF THE INVENTION

The invention relates generally to an interface between a three-phase motor and an inverter, such as an AC carrier, where the interface has at least one electromagnetic interference damping feature and is suitable for use with various combinations of three-phase motors and inverters.

### BACKGROUND OF THE INVENTION

Busbars are generally known and are typically used for providing a mechanical connection and electrical communication between an electric motor and an inverter. Most electric motors which are used in electric vehicles are three-phase electric motors, and require a U-V-W busbar connection to provide the proper current for the electric motor.

Current designs for busbars have performance limitations as a result of electromagnetic interference (EMI) generated by the electric motor and the inverter. There are also limitations on the amount of magnetic flux generated by the electric motor and the inverter. Various combinations of electric motors and inverters for electric vehicles may require different levels of current and voltage. Different levels of current and voltage may result in different levels of EMI. One solution to address EMI is to use a common mode choke, which may be in the form of a core having an aperture, where each of the bus bars extends through the aperture of the core. The size of the core needed varies depending upon the EMI generated by the electric motor and the inverter, and different applications may require a core having different sizes.

Additionally, inverters commonly include the use of flux concentrators to intensity magnetic flux around the busbars. As mentioned above, various combinations of electric motors and inverters for electric vehicles may require different levels of current and voltage, such that the size of the flux concentrators needed may not be the same for every application.

Accordingly, there exists a need for a busbar connection between an inverter and an electric motor which may be suitable for use with common mode choke and flux concentrators of various sizes.

### SUMMARY OF THE INVENTION

The present invention is an interface between a three-phase motor and an inverter, such as an AC carrier, where the interface has at least one electromagnetic interference damping feature.

In an embodiment, the present invention is an AC carrier assembly, which includes a housing, a receptacle integrally formed as part of the housing, a plurality of busbars extending through the housing, a core at least partially disposed in the receptacle, the core surrounding the busbars to dampen electromagnetic interference. The present invention also includes a plurality of sub-housings integrally formed as part of the housing, and a plurality of flux concentrators, where each of the flux concentrators is disposed in a corresponding one of the sub-housings. The present invention also includes a cover attached to the housing, and a plurality of conductors. Each of the conductors is connected one of the busbars, and each of the flux concentrators surrounds a corresponding one of the busbars.

In an embodiment, the cover includes at least one busbar isolation barrier disposed between two of the busbars when the cover is attached to the housing, and at least one anti-drop fastener barrier adjacent one of the busbars when the cover is attached to the housing. The anti-drop fastener barrier is on the opposite side of one of the busbars in relation to the busbar isolation barrier.

In an embodiment, a portion of the core is at least partially disposed in a cavity of the cover.

In an embodiment, each of the sub-housings includes a cavity, and one of the flux concentrators is at least partially disposed in the cavity of one of the sub-housings. In an embodiment, one of the flux concentrators partially protrudes out of the cavity.

In an embodiment, each cavity of each of the sub-housings includes an inner wall, where a portion of one of the busbars is surrounded by the inner wall, and an outer wall surrounding at least a portion of the inner wall. One of the flux concentrators is disposed between the inner wall and the outer wall when disposed in the cavity.

In an embodiment, each of the plurality of sub-housings is overmolded around a corresponding one of the plurality of flux concentrators.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a perspective view of a first embodiment of an AC carrier which has at least one electromagnetic interference damping feature, according to embodiments of the present invention;

FIG. 2 is an exploded view of a first embodiment of an AC carrier which has at least one electromagnetic interference damping feature, according to embodiments of the present invention;

FIG. 3 is a perspective view of a core used as part of a first embodiment of an AC carrier which has at least one electromagnetic interference damping feature, according to embodiments of the present invention;

FIG. 4A is a perspective view of a second embodiment of an AC carrier which has at least one electromagnetic interference damping feature;

FIG. 4B is an exploded view of a second embodiment of an AC carrier which has at least one electromagnetic interference damping feature, according to embodiments of the present invention;

FIG. 4C a perspective view of a core used as part of a second embodiment of an AC carrier which has at least one electromagnetic interference damping feature, according to embodiments of the present invention;

FIG. 4D a perspective view of a flux concentrator used as part of a second embodiment of an AC carrier which has at least one electromagnetic interference damping feature, according to embodiments of the present invention;

FIG. 4E is a sectional view of a portion of a second embodiment of an AC carrier which has at least one electromagnetic interference damping feature, according to embodiments of the present invention;

FIG. 5 is a perspective view of a third embodiment of an AC carrier which has at least one electromagnetic interference damping feature;

FIG. 6A is an exploded view of a fourth embodiment of an AC carrier which has at least one electromagnetic interference damping feature, according to embodiments of the present invention;

FIG. 6B is perspective view of a fourth embodiment of an AC carrier which has at least one electromagnetic interference damping feature, according to embodiments of the present invention;

FIG. 7A is an exploded view of a fifth embodiment of an AC carrier which has at least one electromagnetic interference damping feature, according to embodiments of the present invention; and

FIG. 7B is perspective view of a fifth embodiment of an AC carrier which has at least one electromagnetic interference damping feature, according to embodiments of the present invention.

### DETAILED DESCRIPTION OF THE PREFERRED EMBODIMENTS

The following description of the preferred embodiment(s) is merely exemplary in nature and is in no way intended to limit the invention, its application, or uses.

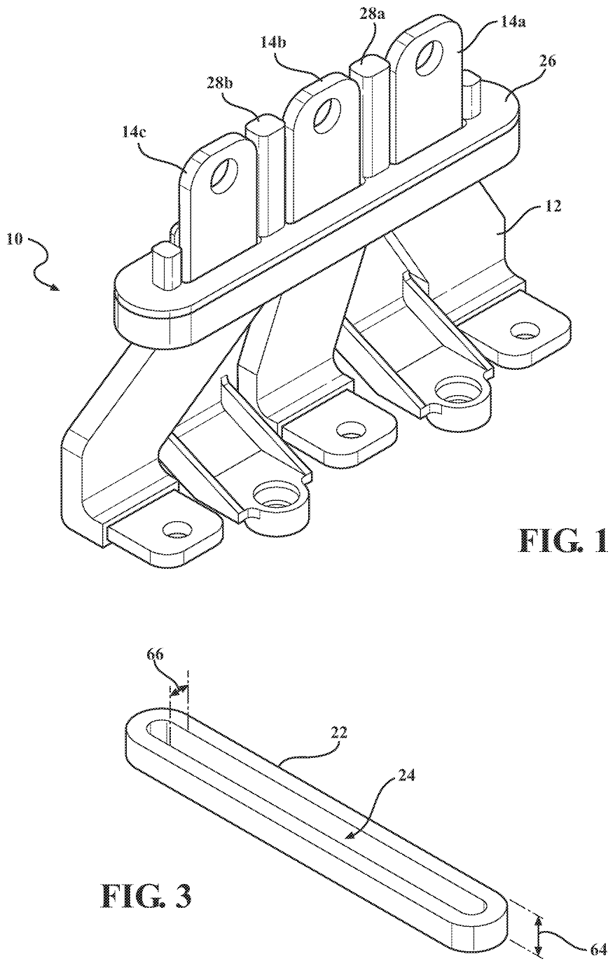

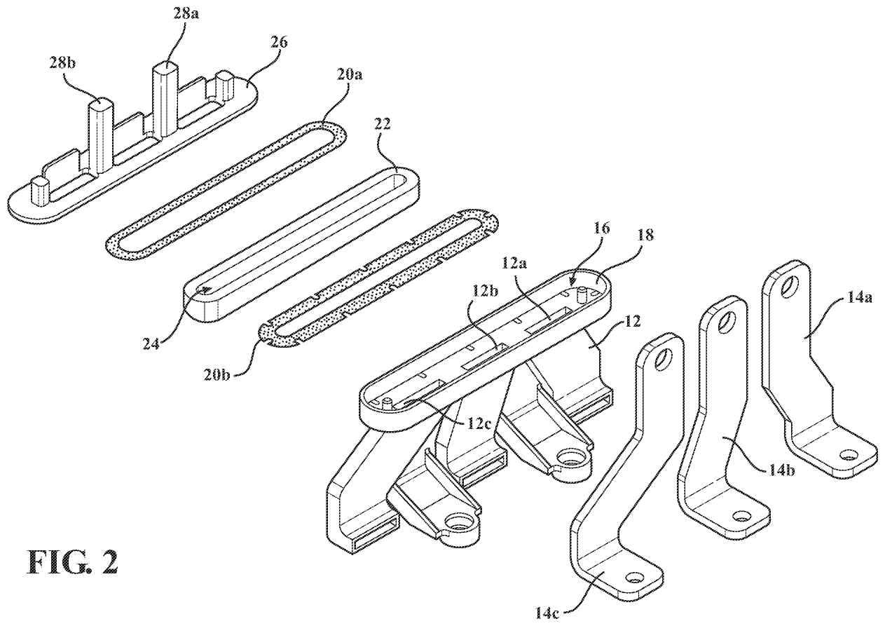

An embodiment of an interface or alternating current (AC) carrier assembly according to the present invention is shown in FIG. 1 generally at 10. Referring to FIGS. 1-2, the AC carrier assembly 10 includes a housing 12, and extending through the housing 12 is a plurality of busbars 14a, 14b, 14c, where each busbar 14a, 14b, 14c has a first end and a second end which protrude from the housing 12. Integrally formed with the housing 12 are apertures 12a, 12b, 12c, where each busbar 14a, 14b, 14c extends through a corresponding one of the apertures 12a, 12b, 12c. Also integrally formed with the housing 12 is a receptacle, shown generally at 16, which has a sidewall 18. Disposed in the receptacle 16 is a first layer of adhesive 20a and a second layer of adhesive 20b, which in the embodiment shown are layers of glue.

Disposed between the first layer of adhesive 20a and the second layer of adhesive 20b is a core 22. In the embodiment shown, the core 22 is made of a Nickle-Zinc soft ferrite material, but it is within the scope of the invention that other materials may be used. The core 22 has an aperture, shown generally at 24, and each of the busbars 14a, 14b, 14c extends through the aperture 24 when the AC carrier assembly 10 is assembled. During operation, the AC carrier assembly 10 provides a connection between an electric motor (not shown) and an inverter (not shown). The core 22 attenuates common mode current peaks which are generated by the switching of the power stage of the inverter, which is capable of causing high levels of electromagnetic interference (EMI). The core 22 reduces the EMI potential of the motor leads of the electric motor and the electric motor itself. The core 22 has the desired impedance to function as an EMI damper. Additionally, the core 22 provides passive EMI damping.

The core 22 has an overall height 64, and the aperture 24 of the core 22 has a width 66. The height 64 of the core 22 and the width 66 of the aperture 24 may be changed, such that the core 22 may still fit in the receptacle 16, and achieve desired EMI damping, such that the AC carrier assembly 10 may be used with different electric motor and inverter applications to reduce EMI potential.

There is also a cover 26 which is connected to the sidewall 18 of the receptacle 16 to prevent the core 22 from being exposed to dust, dirt, and other external debris. Integrally formed with the cover 26 are two busbar isolation barriers 28a,28b, which prevent current leakage, and arcing during testing. More specifically, when the AC carrier assembly 10 is assembled, the first busbar isolation barrier 28a is located between the first busbar 14a and the second busbar 14b, and the second busbar isolation barrier 28b is located between the second busbar 14b and the third busbar 14c.

The housing 12 may be over molded around the busbars 14a, 14b, 14c using an injection molding process, or the like. The cover 26 may be connected to the sidewall 18 using any suitable connection process, such as, but not limited to, laser welding, ultrasonic welding, or the like.

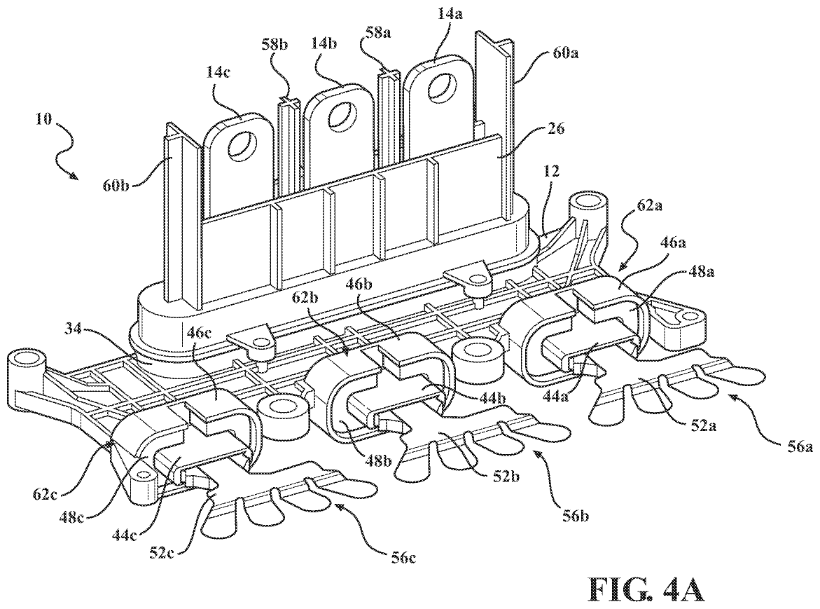

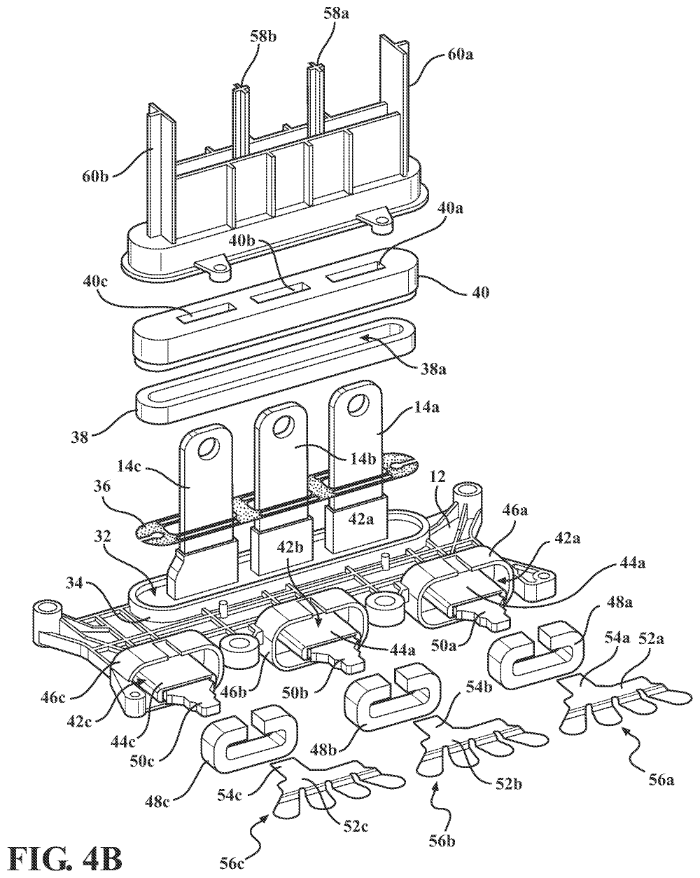

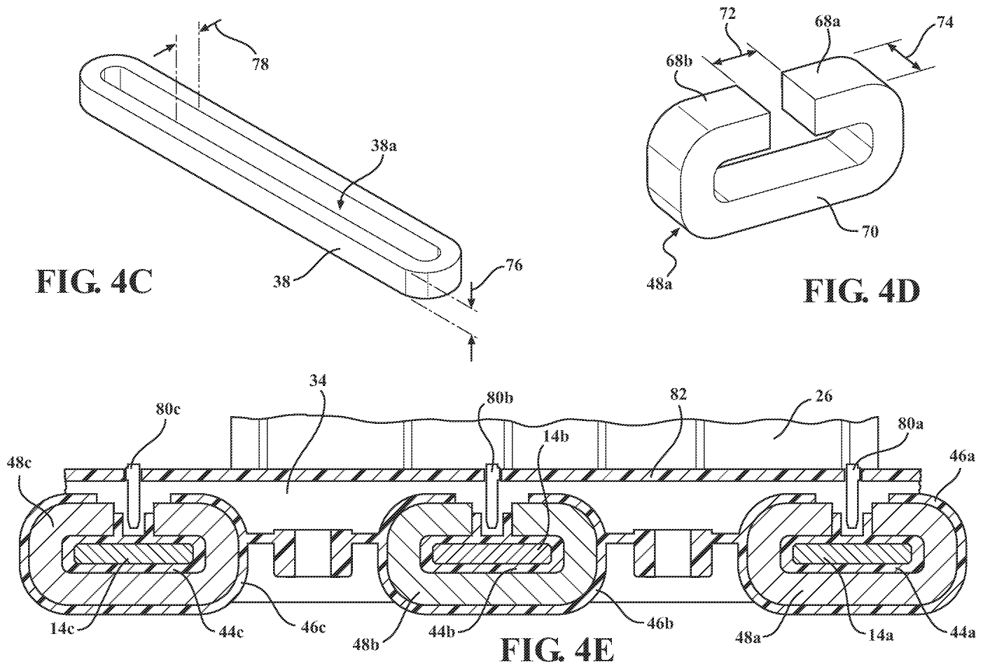

Another embodiment of the present invention is shown in FIGS. 4A-4E, with like numbers referring to like elements. In this embodiment, each of the busbars 14a, 14b, 14c extend through a housing 30. The housing 30 includes apertures (not shown), and each of the busbars 14a, 14b, 14c extend through one of the apertures. Integrally formed with the housing 30 is a receptacle, shown generally at 32, having a sidewall 34. Disposed in the receptacle 32 is a layer of adhesive 36, and partially disposed in the receptacle 32 and adjacent to the layer of adhesive 36 is a core 38 having an aperture, shown generally at 38a, which is similar to the core 22 described in the previous embodiment. The core 38 is held in place in the receptacle 32 by the adhesive 36.

The cover 26 in this embodiment includes a cavity and disposed in the cavity is a potting element 40, and when assembled, the potting element 40 is in contact with the core 38. As mentioned above, the core 38 is partially disposed in the receptacle 32, the core 38 is also partially disposed in the cavity of the cover 26. The potting element 40 is a molded material that is dispensed into the cavity of the cover 26, such that the potting element 40 surrounds a portion of each of the busbars 14a, 14b, 14c. When the molded material solidifies to form the potting element 40, several apertures 40a, 40b, 40c, are formed, through which one of the busbars 14a, 14b, 14c extends. When assembled, in addition to the core 38, each of the busbars 14a, 14b, 14c also extends through the housing 30 and the potting element 40.

The AC carrier assembly 10 shown in FIGS. 4A-4E also includes a plurality of sub-housings. More specifically, each of the sub-housings includes a cavity 42a, 42b, 42c, an inner wall 44a, 44b, 44c, and an outer wall 46a, 46b, 46c. Each inner wall 44a, 44b, 44c and outer wall 46a, 46b, 46c is formed as part of the housing 30, and each inner wall 44a, 44b, 44c surrounds a portion of one of the busbars 14a, 14b, 14c. Located in the first cavity 42a and disposed between the inner wall 44a and the outer wall 46a of the first cavity 42a is a first flux concentrator 48a. Located in the second cavity 42b and disposed between the inner wall 44b and the outer wall 46b of the second cavity 42b is a second flux concentrator 48b. Located in the third cavity 42c and disposed between the inner wall 44c and the outer wall 46c of the third cavity 42c is a third flux concentrator 48c.

In the embodiment shown, each flux concentrator 48a, 48b, 48c is substantially C-shaped, but it is within the scope of the invention that the flux concentrators 48a, 48b, 48c may be different shapes. The shape of the flux concentrators 48a, 48b, 48c concentrates the flux from the current flowing through the busbars 14a, 14b, 14c. Referring now to FIG. 4D, the first flux concentrator 48a is shown, but the following description applies to the other flux concentrators 48b,48c. The flux concentrator 48a is substantially C-shaped as mentioned above, and includes a first flange 68a and a second flange 68b, which are integrally formed with a main body portion 70. There is a gap 72 between the ends of the flanges 68a,68b, and a sensor, such as a Hall Effect current sensor, may be placed in the gap 72 between the ends of the flanges 68a,68b. The Hall Effect current sensor detects the flux from the current flowing through the busbars 14a, 14b, 14c, which facilitates the inverter to be able to control the motor accurately. Referring to FIG. 4E, the Hall Effect current sensors 80a, 80b, 80c are shown disposed in the respective gaps 72 of the flux concentrators 48a, 48b, 48c, and the Hall Effect current sensors 80a, 80b, 80c are mounted to a printed circuit board (PCB) 82. The PCB 82 may be connected to the housing 12 in any suitable manner. The flux concentrator 48a also has a thickness 74, which may be varied. In an embodiment, the thickness 74 may be increased such that the flux concentrator 48a protrudes out of the cavity 42a. The size and shape of the cavities 42a, 42b, 42c allows for the use of flux concentrators 48a, 48b, 48c having various thicknesses 74, allowing the embodiment of the AC carrier 10 in FIGS. 4A-4E to be used with different electric motor and inverter applications.

When the flux concentrators 48a, 48b, 48c are disposed in the corresponding cavities 42a, 42b, 42c, each flux concentrator 48a, 48b, 48c at least partially surrounds one of the busbars 14a, 14b, 14c. The installation of the flux concentrators 48a, 48b, 48c into the corresponding cavities 42a, 42b, 42c achieves the integration of the flux concentrators 48a, 48b, 48c into the AC carrier assembly 10 (instead of being part of the power module of the inverter), improving packaging and electrical spacing clearances, eliminating parts, increasing spacing clearances in the inverter without increasing the overall size of the inverter. In the embodiment shown in FIGS. 3 and 4, the flux concentrators 48a, 48b, 48c held in place in the corresponding cavities 42a, 42b, 42c by gluing, or some other type of adhesive.

Referring to FIG. 4C, as with the previous embodiment, the core 38 has an overall height 76, and the aperture 24 of the core 22 has a width 78. The height 76 of the core 22 and the width 78 of the aperture 24 may be changed, such that the core 22 may still fit in the receptacle 32, and achieve desired EMI damping, such that the AC carrier assembly 10 may be used with different electric motor and inverter applications to reduce EMI potential.

An end 50a, 50b, 50c of each busbar 14a, 14b, 14c protrudes out of the housing 30. There is also several conductors 52a, 52b, 52c which are connected to a corresponding end of one of the busbars 14a, 14b, 14c. More specifically, attached to the end 50a of the first busbar 14a is a connector flange 54a of the first conductor 52a, attached to the end 50b of the second bus bar 14b is a connector flange 54b of the second conductor 52b, and attached to the end 50c of the third busbar 14c is a connector flange 54c the third conductor 52c. Each conductor 52a, 52b, 52c also includes a plurality of power module fingers. More specifically, the first conductor 52a has a first plurality of power module fingers 56a, the second conductor 52b has a plurality of power module fingers 56b, and the third conductor 52c also has a plurality of power module fingers 56c. Each of the plurality of power module fingers 56a, 56b, 56c is connected to one or more of the chips which are part of the inverter. The power module fingers 56a, 56b, 56c function to transfer electrical power from one or more of the chips of the inverter to the busbars 14a, 14b, 14c, or transfer electrical power from the busbars 14a, 14b, 14c to one or more of the chips of the inverter.

In the embodiment shown, each of the conductors 52a, 52b, 52c is a one-piece stamped component, but it is within the scope of the invention that the conductors 52a, 52b, 52c may be made with various manufacturing processes.

Integrally formed as part of the cover 26 in this embodiment are two busbar isolation barriers 58a,58b, which prevent current leakage. Also integrally formed as part of the cover 26 are two anti-drop fastener barriers 60a,60b. The anti-drop fastener barriers 60a,60b prevent fasteners from falling into the inverter during assembly with the electric motor.

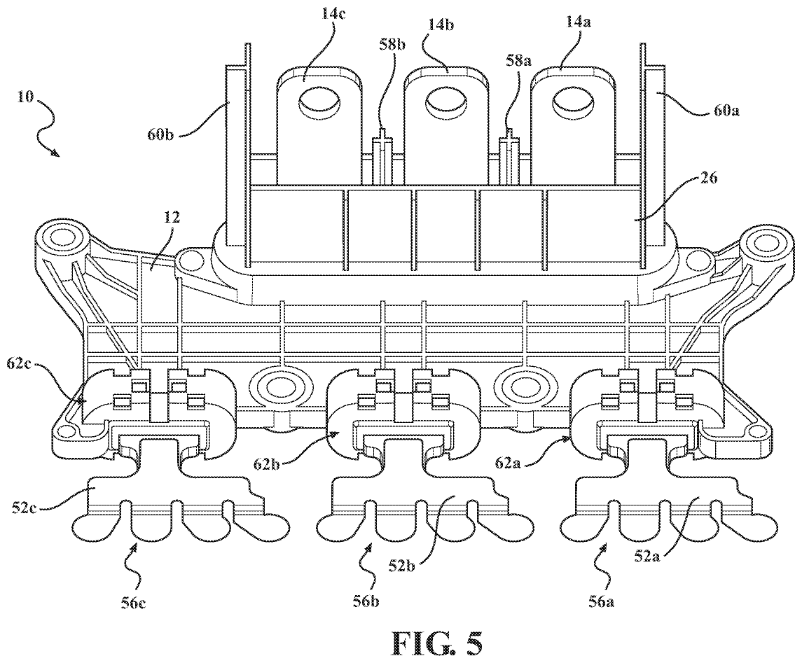

An alternate embodiment of the AC carrier assembly 10 is shown in FIG. 5, with like numbers referring to like elements. In this embodiment, the sub-housings 62a, 62b, 62c integrally formed as part of the housing 30. The sub-housings 62a, 62b, 62c are overmolded around the flux concentrators 48a, 48b, 48c, respectively, during the formation of the housing 30. The housing 30 may be overmolded around portions of the busbars 14a, 14b, 14c and the flux concentrators 48a, 48b, 48c during a single overmolding process. Similar to the embodiment shown in FIGS. 4A-4B, the thickness 74 of the flux concentrators 48a, 48b, 48c may be varied, to accommodate various electric motor and inverter applications. The shape of the outer surface of the sub-housings 62a, 62b, 62c remains the same after the overmolding process. However, the amount and the shape of the molded material inside the sub-housings 62a, 62b, 62c may vary during and after the overmolding process to accommodate the different sizes and shapes of the of the flux concentrators 48a, 48b, 48c used in different applications.

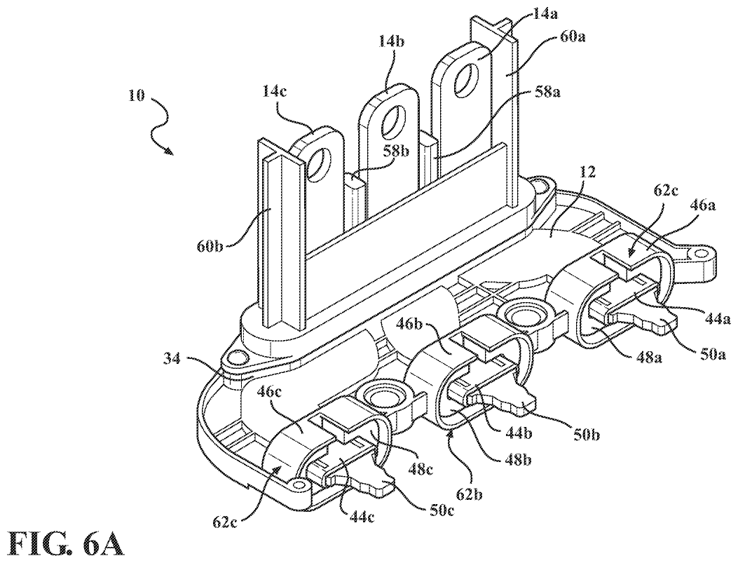

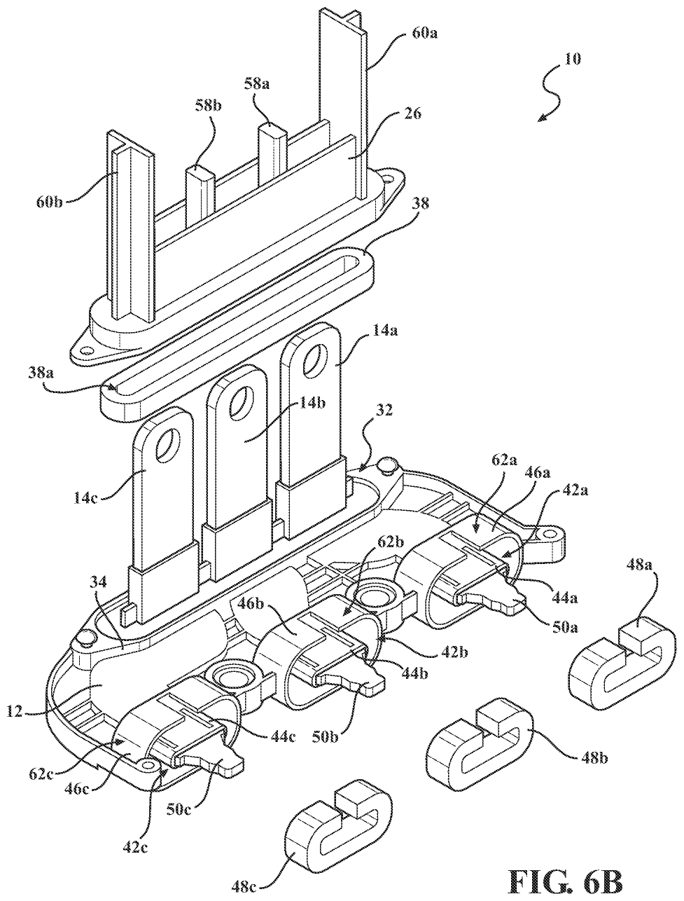

Another embodiment of the present invention is shown in FIGS. 6A-6B, with like numbers referring to like elements. In this embodiment, the flux concentrators 48a, 48b, 48c are located in the corresponding cavities 42a, 42b, 42c. In this embodiment, the housing 30 is shaped differently compared to the housing 30 shown in the embodiment in FIGS. 4A-4E, such that the housing 20 is smaller, has fewer connections, and facilitates meeting more stringent packaging requirements.

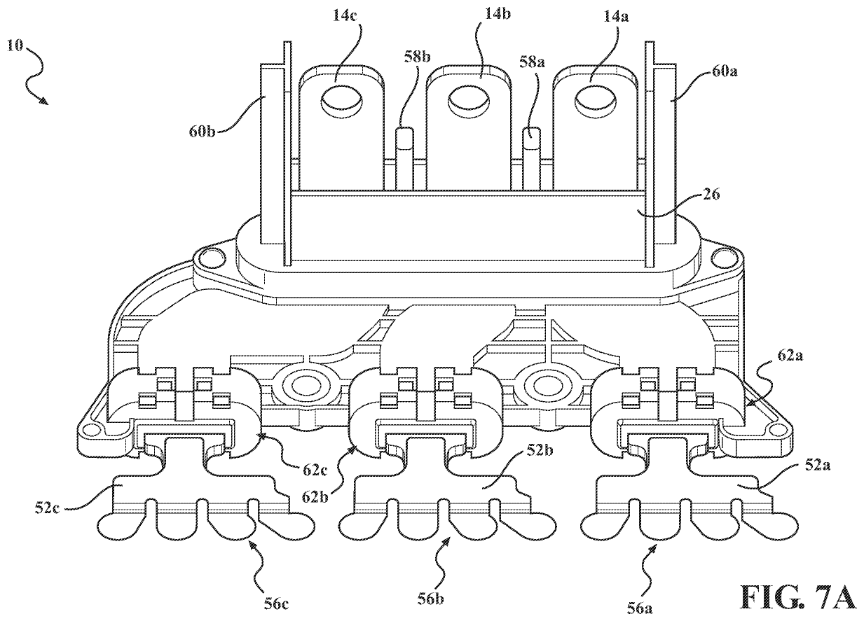

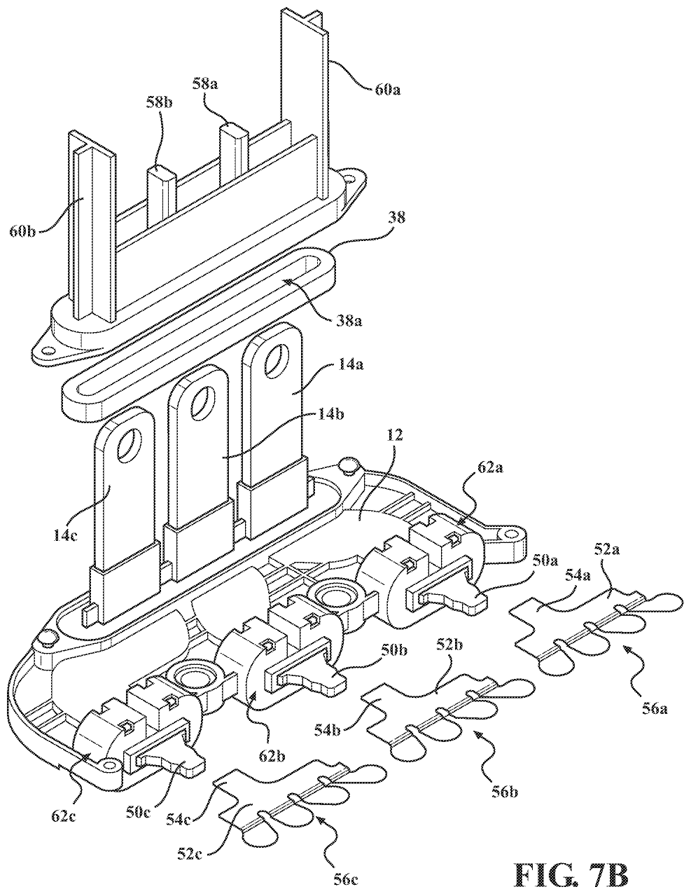

Another embodiment of the present invention is shown in FIGS. 7A-7B, with like numbers referring to like elements. In this embodiment, the housing 30 is similarly shaped to the housing 30 in the embodiment shown in FIGS. 6A-6B, but the sub-housings 62a, 62b, 62c are overmolded around the flux concentrators 48a, 48b, 48c, respectively, during the formation of the housing 30.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. An apparatus, comprising:
an AC carrier assembly, including:
a housing;
a receptacle integrally formed as part of the housing;
a plurality of busbars extending through the housing;
a core at least partially disposed in the receptacle, the core surrounding the plurality of busbars to dampen electromagnetic interference;
a plurality of sub-housings integrally formed as part of the housing; and
a plurality of flux concentrators, each of the plurality of flux concentrators disposed in a corresponding one of the plurality of sub-housings;
wherein each of the plurality of flux concentrators surrounds a portion of a corresponding one of the plurality of busbars.

2. The apparatus of claim 1, further comprising a cover attached to the housing.

3. The apparatus of claim 2, the cover further comprising:
at least one busbar isolation barrier;
wherein the at least one busbar isolation barrier is disposed between two of the plurality of busbars when the cover is attached to the housing.

4. The apparatus of claim 2, the cover further comprising:
at least one anti-drop fastener barrier;
wherein the at least one anti-drop fastener barrier is adjacent one of the plurality of busbars when the cover is attached to the housing.

5. The apparatus of claim 2, wherein a portion of the core is at least partially disposed in a cavity of the cover.

6. The apparatus of claim 1, further comprising a plurality of conductors, wherein each of the plurality of conductors is connected to one of the plurality of busbars.

7. The apparatus of claim 1, each of the plurality of sub-housings further comprising a cavity, one of the plurality of flux concentrators at least partially disposed in the cavity of one of the plurality of sub-housings.

8. The apparatus of claim 7, wherein the one of the plurality of flux concentrators partially protrudes out of the cavity.

9. The apparatus of claim 7, the cavity further comprising:
an inner wall, a portion of one of the plurality of busbars surrounded by the inner wall; and
an outer wall surrounding at least a portion of the inner wall;
wherein the one of the plurality of flux concentrators is disposed between the inner wall and the outer wall when the one of the plurality of flux concentrators is disposed in the cavity.

10. The apparatus of claim 1, wherein each of the plurality of sub-housings is overmolded around a corresponding one of the plurality of flux concentrators.

11. An AC carrier assembly, comprising:
a housing;
a receptacle integrally formed as part of the housing;
a plurality of busbars extending through the housing;
a core at least partially disposed in the receptacle, the core surrounding the plurality of busbars to dampen electromagnetic interference;
a plurality of sub-housings integrally formed as part of the housing;
a plurality of flux concentrators, each of the plurality of flux concentrators disposed in a corresponding one of the plurality of sub-housings;
a cover attached to the housing;
a plurality of conductors, wherein each of the plurality of conductors is connected one of the plurality of busbars;
wherein each of the plurality of flux concentrators surrounds a corresponding one of the plurality of busbars.

12. The AC carrier assembly of claim 11, the cover further comprising:
at least one busbar isolation barrier disposed between two of the plurality of busbars when the cover is attached to the housing; and
at least one anti-drop fastener barrier adjacent one of the plurality of busbars when the cover is attached to the housing;
wherein the at least one anti-drop fastener barrier is on the opposite side of one of the plurality of busbars in relation to the at least one busbar isolation barrier.

13. The AC carrier assembly of claim 11, wherein a portion of the core is at least partially disposed in a cavity of the cover.

14. The AC carrier assembly of claim 11, each of the plurality of sub-housings further comprising a cavity, one of the plurality of flux concentrators at least partially disposed in the cavity of one of the plurality of sub-housings.

15. The AC carrier assembly of claim 14, wherein the one of the plurality of flux concentrators partially protrudes out of the cavity.

16. The AC carrier assembly of claim 14, the cavity further comprising:
an inner wall, a portion of one of the plurality of busbars surrounded by the inner wall; and
an outer wall surrounding at least a portion of the inner wall;
wherein the one of the plurality of flux concentrators is disposed between the inner wall and the outer wall when the one of the plurality of flux concentrators is disposed in the cavity.

17. The AC carrier assembly of claim 11, wherein each of the plurality of sub-housings is overmolded around a corresponding one of the plurality of flux concentrators.
